(19) United States
(12) Patent Application Publication
(10) Pub. No.: US 2006/0220146 A1
(43) Pub. Date: Oct. 5, 2006

(54) Semiconductor device

(75) Inventors: Yasuhiro Takeda, Ogaki-shi (JP); Koji Yamashita, Kofu-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/392,648

(22) Filed: Mar. 30, 2006

(30) Foreign Application Priority Data
Mar. 31, 2005 (JP) 2005-100954
Aug. 23, 2005 (JP) 2005-240906

(51) Int. Cl. H01L 29/76

(52) U.S. Cl. 257/374

(57) ABSTRACT

A semiconductor device for effectively suppressing noise propagation between circuits. The semiconductor device includes a semiconductor substrate having a main surface. Two circuit regions are defined in the semiconductor substrate. A circuit isolation region is located between the two circuit regions. A dummy diffusion layer is formed in the circuit isolation region. The dummy diffusion layer has an upper surface that is lower than the main surface of the semiconductor substrate.

### CROSS-REFERENCE TO RELATED APPLICATIONS

This application is based upon and claims the benefit of priority from prior Japanese Patent Application No. 2005-100954, filed on Mar. 31, 2005, and Japanese Patent Application No. 2005-240906, filed on Aug. 23, 2005, the entire contents of which are incorporated herein by reference.

### BACKGROUND OF THE INVENTION

The present invention relates to a semiconductor device, and more particularly, to suppression of noise propagation between two circuits on a semiconductor substrate.

A technique for forming a circuit isolation region including a dielectric isolation structure through the shallow trench isolation (STI) process is known in the art. In the STI process, a silicon substrate is etched in a state in which a diffusion layer region is masked to form a trench having a predetermined depth in the surface of the silicon substrate at a portion corresponding to where an insulation layer is formed. An oxide film is then deposited on the silicon substrate and embedded in the trench. Unnecessary portions of the oxide film extending out of the trench are removed by performing chemical mechanical polishing (CMP). This flattens the main surface of the silicon substrate. This forms a circuit isolation region including a dielectric isolation structure.

If the circuit isolation region has a large surface area, the CMP process tends to cause dishing in which the circuit isolation region is removed more deeply at the central portion than the peripheral portion. Japanese Laid-Open Patent Publication No. 2002-190516 describes a first prior art example for preventing dishing by arranging a dummy diffusion layer in a circuit isolation region to divide the dielectric isolation structure of the circuit isolation region.

The arrangement of the dummy diffusion layer in the circuit isolation region is effective for preventing dishing. With regard to the suppression of noise propagation, however, the dummy diffusion layer functions as a noise propagation path. It is thus not desirable for the circuit isolation region to include the dummy diffusion layer.

In addition, when a self-aligned silicide (salicide) layer is formed in other diffusion layers or in a gate electrode, the salicide layer may also be formed on the dummy diffusion layer. In such a case, the salicide layer, or the surface layer of the dummy diffusion layer will function as a noise propagation path. This is not desirable for suppressing noise propagation.

Accordingly, Japanese Laid-Open Patent Publication No. 2002-190516 proposes suppression of noise propagation through the surface layer of the dummy diffusion layer. A semiconductor device of the patent publication will be described with reference to FIG. 1. A plurality of dummy diffusion layers 52 isolated by dielectric isolation layers 51 are arranged in a circuit isolation region R3 on a main surface of a silicon substrate 50. The upper surface of the dummy diffusion layers 52 is covered by a dummy gate electrode 53. The dummy gate electrode 53 prevents the formation of a salicide layer on the dummy diffusion layers 52. This suppresses the propagation of noise through the surface layers of the dummy diffusion layer 52. However, the dummy gate electrode 53 does not function to suppress the propagation of noise in a well that acts as the main noise propagation path. In order to suppress noise propagation in the well, an additional structure such as a triple-well structure would be necessary. This would further complicate the configuration of the semiconductor device.

FIGS. 2 and 3 show a second prior art example for preventing noise propagation in an integrated circuit having both analog and digital circuits. In this integrated circuit, a circuit isolation region R3 is formed between an analog circuit region R1 and a digital circuit region R2. A p-type impurity region 103A (in this example, the well of the p-type impurity region 103A is identical to a p-type well 103 of the analog circuit region R1 and a p-type well 103 of the digital circuit region R2) is formed in the circuit isolation region R3. A P+ diffusion layer 106, which is maintained at ground potential through a ground electrode 105, is arranged in the p-type impurity region 103A along a side adjacent to one of the circuit regions (preferably, the side adjacent to the digital circuit region R2). The P+ diffusion layer 106 prevents noise generated in the digital circuit region R2 from entering the analog circuit region R1.

FIG. 2 shows the integrated circuit having both analog and digital circuits. FIG. 3 is a cross-sectional view taken along line 3-3 of FIG. 2. As shown in FIGS. 2 and 3, n-type wells 102 and p-type wells 103 containing impurities at a higher concentration than a p-type semiconductor substrate 101 are formed adjacent to each other in the vicinity of the surface of the p-type semiconductor substrate 101. The analog circuit region R1 and the digital circuit region R2, each having portions included in the n-type and the p-type wells 102 and 103 are arranged on opposite sides of the circuit isolation region R3. The circuit isolation region R3 includes the p-type impurity region 103A. The p-type impurity region 103A is a well identical to the p-type well 103 in the analog circuit region and the p-type well 103 in the digital circuit region.

The structure shown in FIGS. 2 and 3 can only reduce the noise propagated in the surface of the p-type impurity region 103A. The resistivity of the p-type impurity region 103A is extremely low (for example, a resistivity of 0.3 Ω·cm for an impurity concentration of 1×10¹⁷ cm⁻³) in comparison with that of the p-type semiconductor substrate 101 (for example, a resistivity of 12 Ω·cm for an impurity concentration of 1×10¹⁵ cm⁻³). The structure shown in FIGS. 2 and 3 therefore cannot reduce the noise propagated in the p-type impurity region 103A.

Accordingly, Japanese Laid-Open Patent Publication No. 6-326260 describes a third prior art example in which a p-type semiconductor substrate 101 includes a region 101A, which has high resistance like the substrate 101, arranged in the circuit isolation region R3 between the analog circuit region R1 and the digital circuit region R2. This reduces noise propagation in the circuit isolation region R3.

The integrated circuit having both analog and digital circuits described in Japanese Laid-Open Patent Publication No. 6-326260 will now be described with reference to FIGS. 4 and 5. N-type wells 102 and p-type wells 103 containing impurities at a higher concentration than the p-type semiconductor substrate 101 are formed adjacent to each other in the vicinity of the surface of the p-type semiconductor substrate 101. The analog circuit region R1 and the digital circuit region R2 have portions including both the n-type and p-type wells 103. The high-resistance region 101A having neither the n-type well 102 nor the p-type well 103 extends between the analog circuit region R1 and the digital circuit region R2. The high-resistance region 101A functions as a circuit isolation region R3.

When the p-type semiconductor substrate 101 (101A) having a high resistance is provided in the circuit isolation region R3, the electric resistance of the noise propagation path increases. This enables attenuation of high-frequency noise components propagated from the digital circuit region R2 to the analog circuit region R1. However, the amount of dissolved oxygen in the p-type semiconductor substrate 101 must be reduced to increase the resistance of the p-type semiconductor substrate 101. The reduction of dissolved oxygen results in a shortcoming in that slip lines tend to form in the p-type semiconductor substrate 101 when the p-type semiconductor substrate 101 is manufactured. Further, overdoping of impurities must be avoided during heat treatment to keep the impurity concentration low (preferably, at 1×10¹⁵ cm⁻³ or lower) at the surface of the p-type semiconductor substrate 101 (particularly in the circuit isolation region R3). This hinders manufacturing stability.

### SUMMARY OF THE INVENTION

The present invention provides a semiconductor device for effectively suppressing noise propagation between circuits.

One aspect of the present invention is a semiconductor device including a semiconductor substrate having a main surface. Two circuit regions are defined in the semiconductor substrate. A circuit isolation region is located between the two circuit regions. A dummy diffusion layer is formed in the circuit isolation region. The dummy diffusion layer has an upper surface that is lower than the main surface of the semiconductor substrate.

A further aspect of the present invention is a method for manufacturing a semiconductor device including a semiconductor substrate having a main surface. Two circuit regions are defined in the semiconductor substrate. A circuit isolation region is located between the two circuit regions. The method includes the steps of removing part of the main surface in the circuit isolation region, and forming a dummy diffusion layer in the circuit isolation region by implanting impurities in the removed part. The dummy diffusion layer has an upper surface that is lower level than the main surface of the semiconductor substrate.

Another aspect of the present invention is a semiconductor device including a semiconductor substrate. A first circuit region and a second circuit region are defined in the semiconductor substrate. A circuit isolation region is located between the first and second circuit regions. The circuit isolation region includes a depletion layer.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a partial cross-sectional view of a semiconductor device in a first example of the prior art;

FIG. 2 is a plan view showing a semiconductor device having both analog and digital circuits in a second example of the prior art;

FIG. 3 is a cross-sectional view taken along line 3-3 in FIG. 2;

FIG. 4 is a plan view of a semiconductor device having both analog and digital circuits in a third example of the prior art;

FIG. 5 is a cross-sectional view taken along line 5-5 in FIG. 4;

FIG. 6 is a partial cross-sectional view of a semiconductor device according to a first embodiment of the present invention;

FIG. 7 is a diagram showing a noise propagation path in a circuit isolation region of the semiconductor device shown in FIG. 6;

FIGS. 8A to 8G are cross-sectional views showing a manufacturing method for the semiconductor device of FIG. 6;

FIG. 9 is a plan view showing a semiconductor device having both analog and digital circuits according to a second embodiment of the present invention;

FIG. 10 is a cross-sectional view taken along line 10-10 in FIG. 9;

FIG. 11 is a partially enlarged cross-sectional view of a circuit isolation region in the semiconductor device shown in FIG. 10;

FIG. 12 is a diagram showing the frequency dependency of noise power (S21 parameter) transmitted to elements in a p-type well;

FIG. 13 is diagram showing the relationship between the quantity of n-type diffusion layers and noise power (S21 parameter); and

FIG. 14 is a cross-sectional view of a semiconductor device having both analog and digital circuits according to a third embodiment of the present invention.

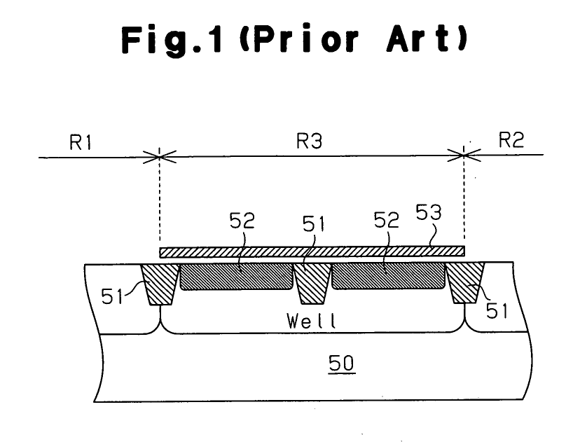

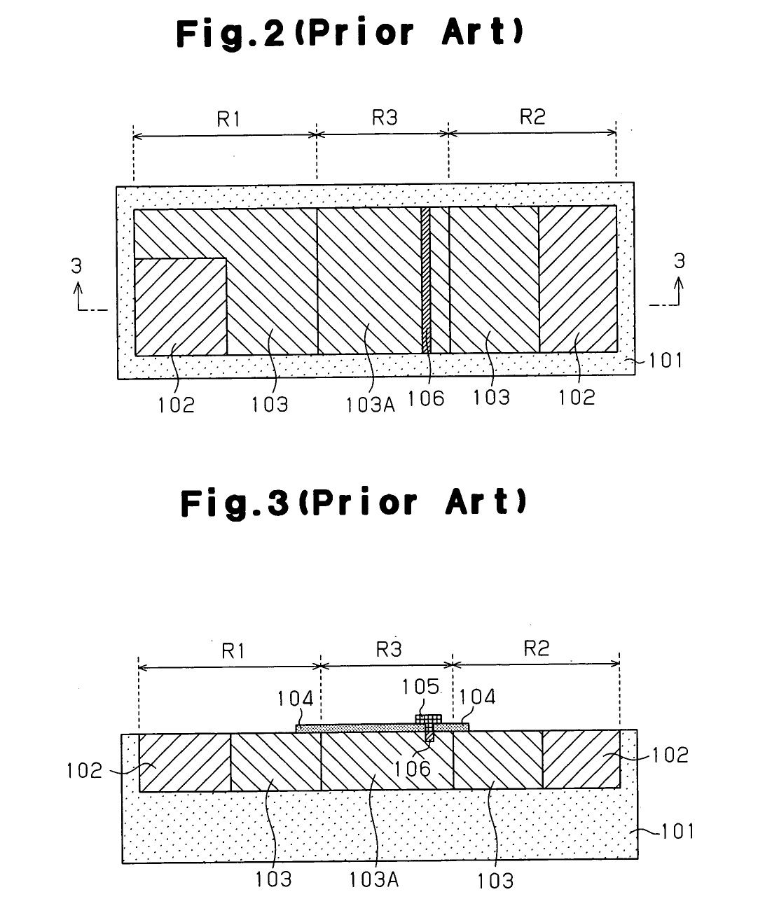

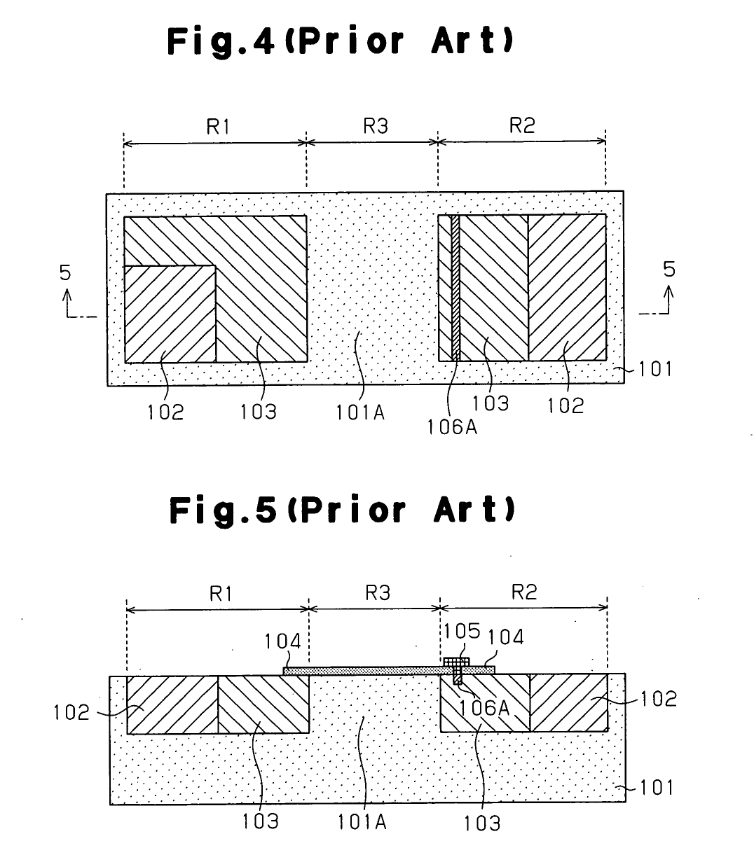

### DETAILED DESCRIPTION OF THE PREFERRED EMBODIMENTS

Semiconductor devices for suppressing noise propagation according to preferred embodiments of the present invention will now be discussed.

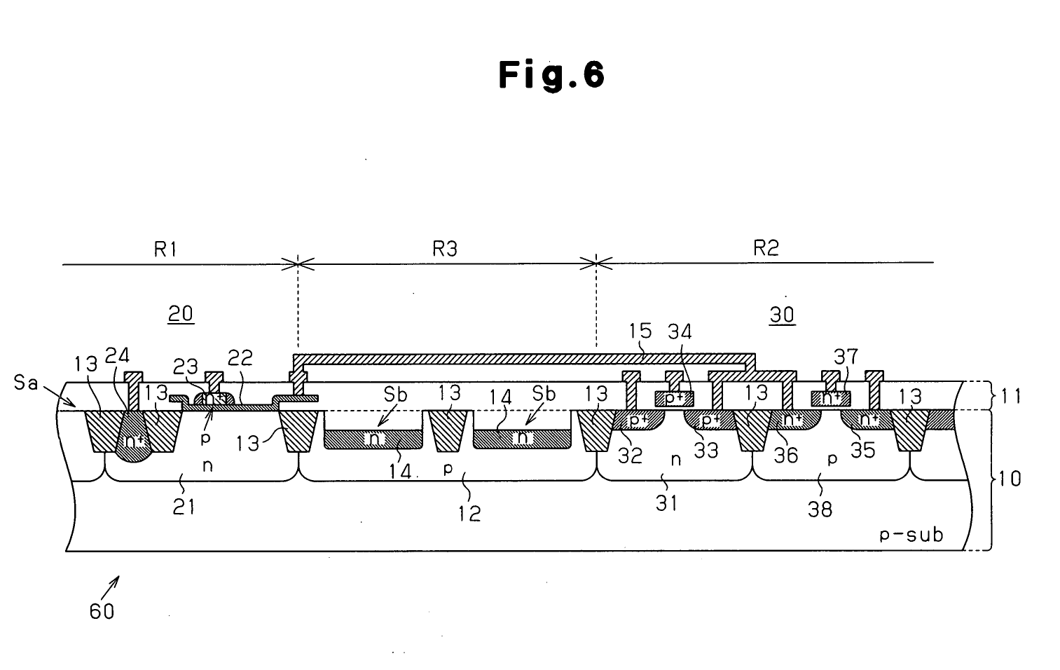

FIG. 6 is a partial cross-sectional view showing a semiconductor device 60 according to a first embodiment of the present invention. An analog circuit region R1 for forming an analog circuit and a digital circuit region R2 for forming a digital circuit are defined in a silicon substrate 10 on opposite sides of a circuit isolation region R3. The circuit isolation region R3 has a width of about 100 to 200 micrometers.

An insulation film layer 11 of silicon oxide is formed on a main surface Sa of the silicon substrate 10. Aluminum signal wires are laid out in the upper portion of the insulation film layer 11 to electrically connect devices. The signal wires include a signal wire 15 extending across the circuit isolation region R3 to electrically connect the analog circuit region R1 and the digital circuit region R2.

The analog circuit in the analog circuit region R1 includes a bipolar transistor 20. The digital circuit in the digital circuit region R2 includes a complementary metal oxide semiconductor (CMOS) transistor 30. FIG. 6 partially shows the analog circuit region R1 and the digital circuit region R2. The analog circuit region R1 and the digital circuit region R2 include other devices that are not shown in FIG. 6.

The bipolar transistor 20 in the analog circuit region R1 includes an n-type collector well 21 formed in the silicon substrate 10, a base region 22 formed on the collector well 21, and an emitter region 23 formed on the base region 22.

The base region 22 is formed by a p-type epitaxial silicon layer, which is epitaxially grown on the collector well 21. The emitter region 23 is formed by an n-type polycrystalline silicon layer applied to the base region 22 through a chemical vapor deposition (CVD) process. The surface of the collector well 21 is isolated into two active regions by a dielectric isolation layer 13 formed through the STI process. One of these two active regions includes the base region 22 and the emitter region 23, while the other one of the two active regions includes a collector leading portion 24. The collector leading portion 24 is implanted with a high concentration of n-type impurities. The dielectric isolation layer 13 is formed in the main surface Sa of the silicon substrate 10 through the STI process so as to surround the periphery of the bipolar transistor 20.

An n-type well 31 and a p-type well 38 are formed in the silicon substrate 10. The CMOS transistor 30 in the digital circuit region R2 includes a pMOS formed on the n-type well 31 and an nMOS formed on the p-type well 38. The pMOS includes a source 32 and a drain 33, which are both formed by p-type diffusion layers in the surface layer of the n-type well 31, and a p-type polycrystalline silicon gate 34 formed above the source 32 and drain 33. An insulation film is arranged between the main surface Sa of the silicon substrate 10 and the p-type polycrystalline silicon gate 34. The nMOS includes a source 35 and a drain 36, which are both formed by n-type diffusion layers in the surface layer of the p-type well 38, and an n-type polycrystalline silicon gate 37 formed above the source 35 and drain 36. An insulation film is arranged between the main surface Sa of the silicon substrate 10 and the n-type polycrystalline silicon gate 37. A dielectric isolation layer 13 is formed through the STI process in the silicon substrate 10 so as to isolate the pMOS and the nMOS and surround the periphery of the CMOS transistor 30. The lower end of the dielectric isolation layer 13 is lower than the main surface Sa.

A p-type well 12 is formed in the circuit isolation region R3 of the silicon substrate 10. A plurality of dummy diffusion layers 14 (only two are shown), which contain n-type impurities, are arranged in the p-type well 12 at locations lower than the main surface Sa of the silicon substrate 10. A dielectric isolation layer 13 is formed through the STI process in the circuit isolation region R3 so as to surround the periphery of the dummy diffusion layers 14.

The dummy diffusion layers 14 are lower than the main surface Sa of the silicon substrate 10. The lower surface of the insulation film layer 11 (the interface between the silicon substrate 10 and the insulation film layer 11) extends downward and into the silicon substrate 10 at a portion corresponding to the dummy diffusion layers 14. It is preferred that the depth from the main surface Sa of the silicon substrate 10 to the upper surfaces Sb of the dummy diffusion layers 14 be substantially the same as the depth at which a PN junction is formed in the interface between a well and the bottom layer of a diffusion layer formed therein for the devices in each circuit region.

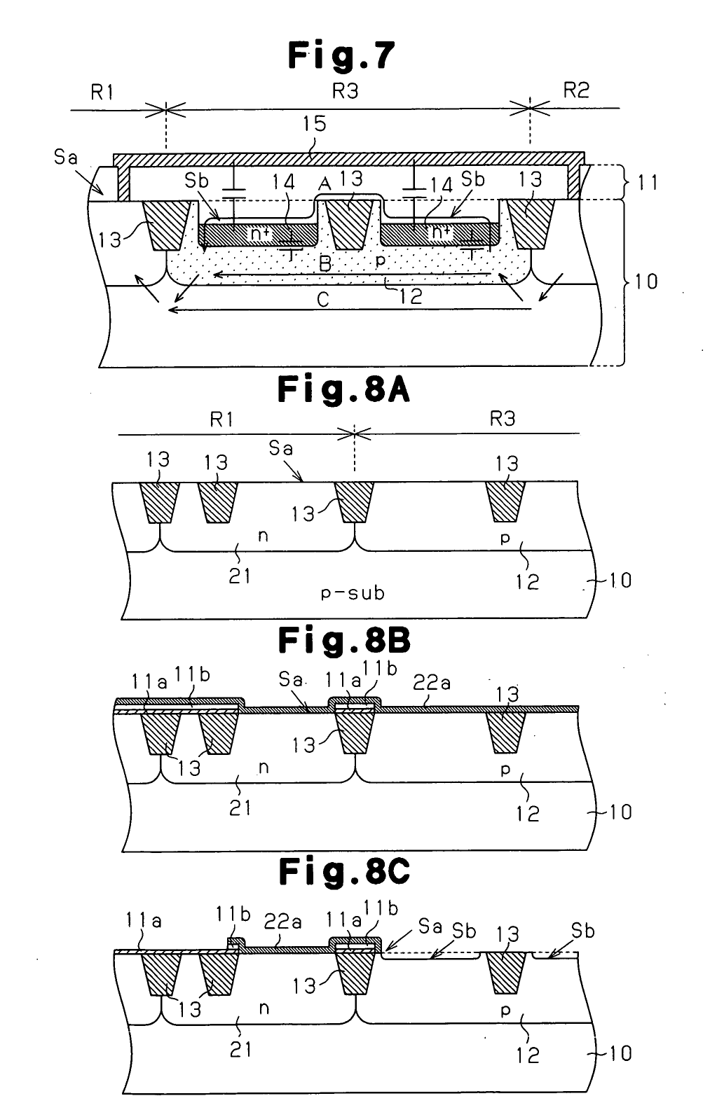

Referring to FIG. 7, noise propagation between the analog circuit region R1 and the digital circuit region R2 will now be described. Noise generated in the digital circuit region R2 is propagated to the analog circuit region R1 mainly through three noise propagation paths A to C. Noise propagation path A extends through the surface layer of the silicon substrate 10 and the interface between the silicon substrate 10 and the insulation film layer 11 in the circuit isolation region R3. Noise propagation path B extends through the p-type well 12 in the circuit isolation region R3. Noise propagation path C extends through the base of the silicon substrate 10. Among the three noise propagation paths A to C, noise propagation path B has the highest influence on the propagation of noise.

In the semiconductor device 60 of the first embodiment, the upper surface Sb of each dummy diffusion layer 14 in the circuit isolation region R3 is lower than the main surface Sa of the silicon substrate 10. This lengthens the noise propagation path A. Thus, the electric resistance of the noise propagation path A is increased, and the noise propagation through the noise propagation path A is suppressed.

In the semiconductor device 60 of the first embodiment, each dummy diffusion layer 14 contains n-type impurities, or impurities having a conductivity type opposite to that of the p-type well 12. Capacitor coupling occurs between the dummy diffusion layer 14 and the p-type well 12, which have opposite conductivity types. This suppresses propagation of low frequency components in the noise between the dummy diffusion layer 14 and the p-type well 12. Additionally, the dummy diffusion layers 14 and the p-type well 12, which is the base material of the dummy diffusion layer 14, are electrostatically insulated by a depletion layer. This narrows the noise propagation path B and increases electric resistance. Accordingly, the propagation of high frequency components of noise through the propagation path B is also suppressed.

In the semiconductor device 60 of the first embodiment, the upper surfaces Sb of the dummy diffusion layers 14 are lower than the main surface Sa of the silicon substrate 10. This spaces the signal wire 15, which extends over the circuit isolation region R3, from the dummy diffusion layers 14 and reduces the parasitic capacitance generated between the signal wire 15 and the dummy diffusion layers 14. As a result, the deterioration of a signal transmitted through the signal wire 15 is suppressed, and the influence of noise on devices driven by the signal is reduced.

The manufacturing of the semiconductor device 60 of the first embodiment will now be described.

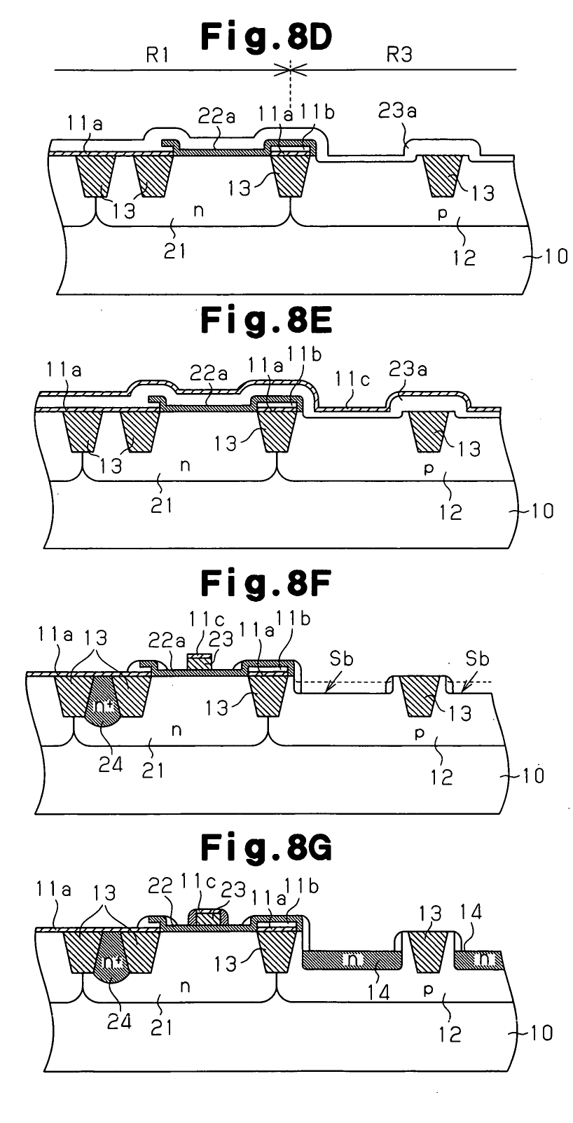

As shown in FIG. 8A, the dielectric isolation layers 13 are formed in the silicon substrate 10 through the STI process. Wells, such as the collector well 21 of the bipolar transistor 20, the p-type well 12 of the circuit isolation region R, and the n-type and p-type wells 31 and 38 of the CMOS transistor 30, are formed by performing ion implantation or the like.

As shown in FIG. 8B, an insulation film 11a and a laminated film 11b of polycrystalline silicon are formed on the silicon substrate 10. These films are then masked to expose only the areas where the base region 22 of the bipolar transistor 20 and the dummy diffusion layers 14 are to be formed. Then, a silicon film 22a for forming the base region 22 is epitaxially grown.

As shown in FIG. 8C, unnecessary portions of the silicon film 22a are etched off. During this etching process, the portions of the p-type well 12 where the dummy diffusion layers 14 are to be formed are removed by performing over-etching so that the upper surface Sb of the p-type well 12 becomes lower than the main surface Sa of the silicon substrate 10.

As shown in FIG. 8D, a polycrystalline silicon film 23a for forming the emitter region 23 of the bipolar transistor 20 is formed on the silicon substrate 10 through the CVD process. The polycrystalline silicon film 23a is then doped through ion implantation.

As shown in FIG. 8E, a silicon nitride film 11c serving as an implantation mask is applied to the polycrystalline silicon film 23a.

As shown FIG. 8F, unnecessary portions of the polycrystalline silicon film 23a are etched off. During this etching process, the portions of the p-type well 12 where the dummy diffusion layers 14 are to be formed are over-etched and removed again so that the upper surface Sb of the p-type well 12 becomes further lower than the main surface Sa of the silicon substrate 10.

Normally, when the base region 22 and the emitter region 23 are processed to form electrodes of the bipolar transistor 20, the main surface Sa of the silicon substrate 10 is entirely masked except for the portions where the electrodes are to be formed. In the first embodiment, however, the upper surfaces Sb of the portions where the dummy diffusion layers 14 are to be formed are not masked but exposed. Therefore, the portions where the electrodes are to be formed are etched off simultaneously and in parallel with the formation of the electrodes of the bipolar transistor 20 so that the upper surfaces Sb of the dummy diffusion layers 14 become lower than the main surface Sa of the silicon substrate 10.

After the formation of the electrodes of the bipolar transistor 20, ion implantation is performed to form the collector leading portion 24 and an external base layer, as shown FIG. 8G. Impurity ions having n-type conductivity are implanted into the etched portions where the dummy diffusion layers 14 are to be formed. In parallel with the formation of the bipolar transistor 20 and the circuit isolation region R3, the polycrystalline silicon gates 34 and 37, sources 32 and 35, and drains 33 and 36 of the CMOS transistor 30 are also formed. Further, the insulation film layer 11, the signal wire, and the electrodes are formed on the silicon substrate 10. This manufactures the semiconductor device 60 shown in FIG. 6.

The first embodiment has the advantages described below.

The upper surfaces Sb of the dummy diffusion layer 14 are lowered so as to lengthen the noise propagation path extending through the surface layer of the circuit isolation region R3. This increases the electric resistance of the noise propagation path extending through the surface layer of the circuit isolation region. Accordingly, noise propagation through the surface layer is effectively suppressed.

The dummy diffusion layers 14 have a conductivity type opposite to that of the p-type well 12, which is the base material of the dummy diffusion layers 14. As a result, capacitor coupling occurs between the dummy diffusion layers 14 and the p-type well 12. This electrostatically insulates the dummy diffusion layers 14 from the p-type well 12 and narrows the noise propagation path. Therefore, noise propagation through the p-type well 12 is suppressed. In particular, capacitor coupling suppresses the propagation of low frequency components in the noise between the dummy diffusion layers 14 and the p-type well 12 (the base material of the dummy diffusion layers 14). Further, the narrowing of the noise propagation path increases the electric resistance of the noise propagation path and suppresses the propagation of high frequency components in the noise.

The p-type well 12 (the base material for the dummy diffusion layers 14) is thin. Hence, in addition to noise propagation through the surface layer of the circuit isolation region R3, noise propagation through the base material of the dummy diffusion layers 14 is suppressed.

The dummy diffusion layers 14 are lowered and spaced from the signal wire 15 extending over the circuit isolation region R3. The parasitic capacitance generated between the signal wire 15 and the dummy diffusion layers 14 is thus reduced. Hence, signal deterioration in the signal wire 15 is suppressed, and the influence of noise is reduced.

The etching and lowering of the upper surface Sb of the dummy diffusion layers 14 is performed simultaneously and in parallel with the formation of the electrodes of the bipolar transistor 20. Therefore, new and additional manufacturing processes are not necessary to manufacture the semiconductor device.

The noise propagation path extending through the surface layer of the circuit isolation region R3 is lengthened regardless of whether the depth of the upper surface Sb of each dummy diffusion layer 14, or the distance between the main surface Sa and the upper surface Sb, is greater or smaller than the depth at which the PN junctions of the devices are formed. Therefore, noise propagation in the surface layer is effectively suppressed.

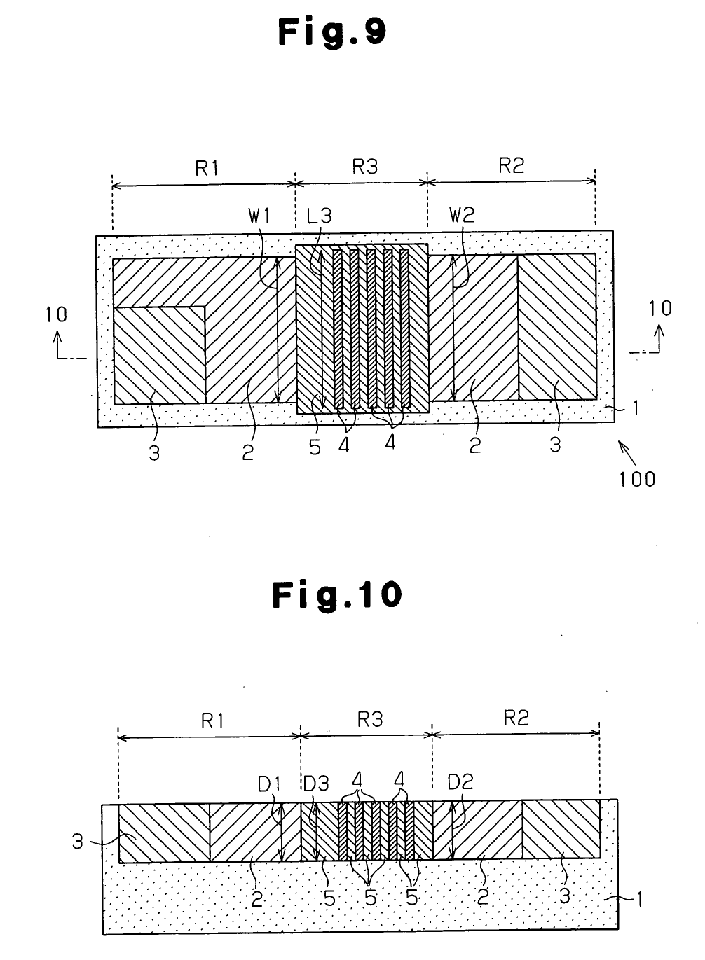

A semiconductor device 100 having both analog and digital circuits according to a second embodiment of the present invention will now be described with reference to FIGS. 9 and 10. FIG. 10 does not show devices included in the circuit regions and insulation films and electrodes on the main surface.

As shown in FIGS. 9 and 10, n-type wells 2 and p-type wells 3 are formed in the vicinity of the surface of a p-type silicon substrate 1. The n-type wells 2 are each adjacent to a corresponding one of the p-type wells 3. The p-type wells 3 contain impurities at a higher concentration than the p-type silicon substrate 1 (containing impurities at a concentration of 1×10¹⁵ cm⁻³). For example, the peak concentration of impurities in the p-type wells 3 is 1×10¹⁸ cm⁻³ and the peak concentration of impurities in the n-type wells 2 is 1×10¹⁸ cm⁻³. The analog circuit region R1 and the digital circuit region R2 each include at least one n-type well 2 and at least one p-type well 3. A circuit isolation region R3 is formed between the analog circuit region R1 and the digital circuit region R2. The circuit isolation region R3 includes a p-type impurity region 5, which is formed in the vicinity of the surface of the p-type silicon substrate 1 and contains a higher concentration of impurities (the peak concentration of the impurities being 1×10¹⁸ cm⁻³) than the p-type silicon substrate 1, and a plurality of n-type diffusion layers 4 formed in the p-type impurity region 5 (the peak concentration of the impurities being 1×10¹⁸ cm⁻³) The n-type diffusion layers 4 extend parallel to each other and to the analog circuit region R1 and the digital circuit region R2. The n-type diffusion layers 4 are parallel and extend in a direction intersecting with a line connecting the analog circuit region R1 and the digital circuit region R2. The n-type diffusion layers 4 have a length L3 (the dimension measured along a first direction) that is greater than the width W1 (the dimension measured along the first direction) of the analog circuit region R1 and the width W2 (the dimension measured along the first direction) of the digital circuit region R2. Further, the depth D3 of the p-type impurity region 5 and the n-type diffusion layers 4 is set to be at least equal to the depth D1 of the analog circuit region R1 and the depth D2 of the digital circuit region R2. The width of the circuit isolation region R3 (the space between the analog circuit region R1 and the digital circuit region R2) is about 20 μm to 200 μm. Within the circuit isolation region R3, five n-type diffusion layers 4 having a width of 2 μm are arranged in parallel at intervals of 2 μm. Thus, the total width of the n-type diffusion layers 4 is 10 μm.

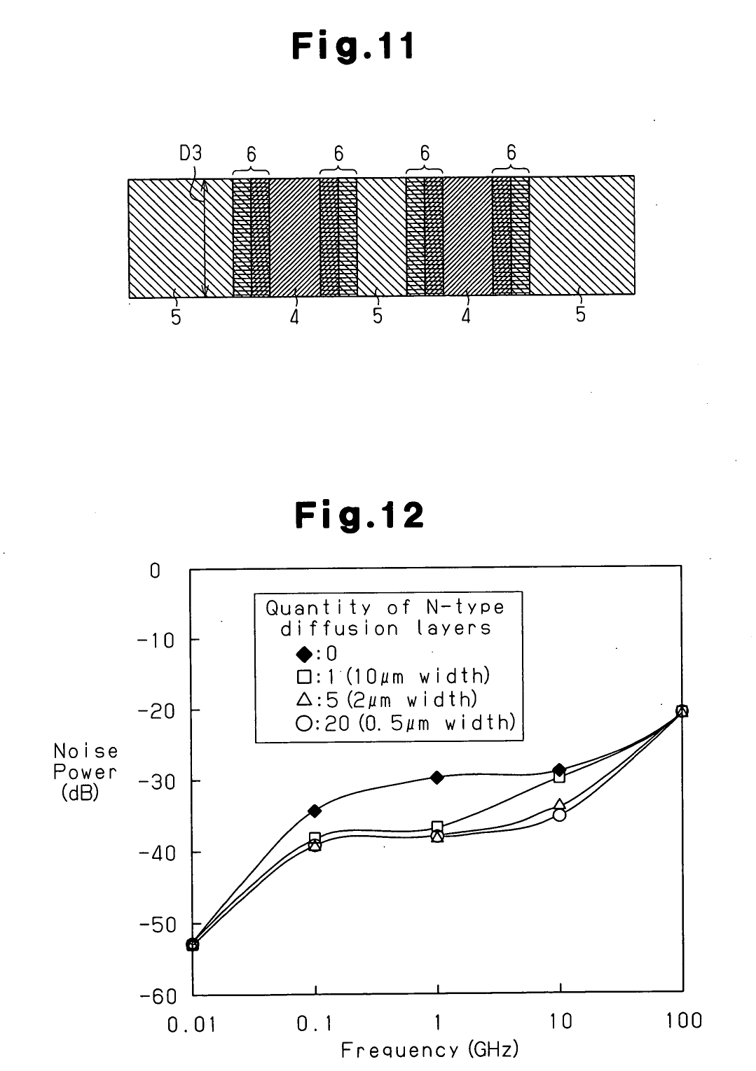

FIG. 11 is a partially enlarged cross-sectional view of the circuit isolation region R3 in the semiconductor device 100. In the semiconductor device 100 having both analog and digital circuits, as shown in FIG. 11, depletion layers 6 (regions where no carriers such as electrons or holes exist) are formed due to the PN junction between the p-type impurity region 5 and the n-type diffusion layers 4. The depletion layers 6 are formed along the interfaces between the n-type diffusion layers 4 and the p-type impurity region 5. Thus, in the same manner as the n-type diffusion layers 4, the depletion layers 6 are parallel and extend in a direction intersecting with a line connecting the analog circuit region R1 and the digital circuit region R2. Further, the depletion layers 6 also have a length greater than the widths W1 and W2 of the analog circuit region R1 and the digital circuit region R2. The depth of the depletion layers 6 is set to be equal to the depth D1 of the analog circuit region R1 and the depth D2 of the digital circuit region R2.

The depletion layers 6, in which no carriers such as electrons or holes exist, exhibit higher resistance than the n-type diffusion layers 4 and p-type impurity regions 5. The employment of a plurality of (e.g., ten) depletion layers 6 increases the resistance of the circuit isolation region R3 between the analog circuit region R1 and the digital circuit region R2 and reduces the conductance of the circuit isolation region R3. Accordingly, the electric resistance of the noise propagation path is increased, and noise propagation between the circuit regions is suppressed.

The five n-type diffusion layers 4 have a length L3 greater than the widths W1 and W2 of the two circuit regions and extend parallel to one another. The n-type diffusion layers 4 are formed to have a depth D3 that is the same as the depths D1 and D2 of the two circuit regions. Thus, ten depletion layers 6 are got across between the circuits. Accordingly, the resistance of the circuit isolation region R3 is further increased, and noise propagation between the two circuits is more effectively suppressed.

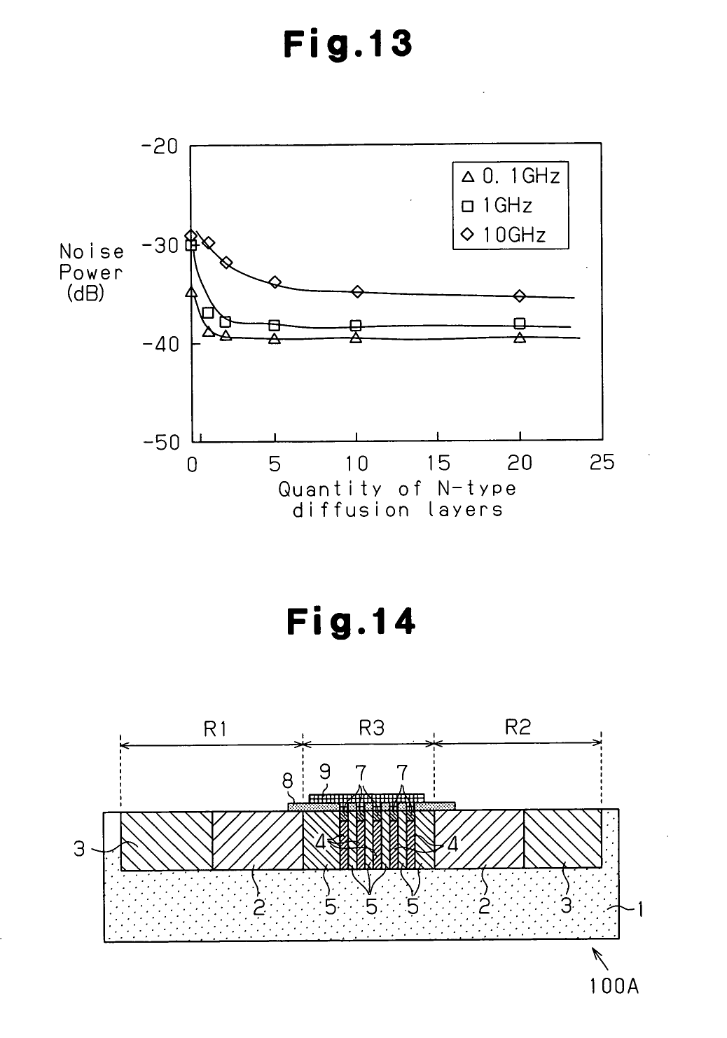

Examples confirming that the circuit isolation region R3 in the second embodiment of present invention is effective for suppressing the propagation of high-frequency noise will now be discussed with reference to FIG. 12 and FIG. 13.

In a semiconductor device including a circuit isolation region having a width of 50 μm, the frequency dependency of noise power (S21 parameter) transmitted from a PN junction element on a p-type well to a device on the p-type well was measured for the following samples. Sample (a) had no n-type diffusion layers 4, sample (b) had one n-type diffusion layer 4 with a width of 10 μm, sample (c) had five n-type diffusion layers 4 with a width of 2 μm, and sample (d) had twenty n-type diffusion layers 4 with a width of 0.5 μm. The results are shown in FIG. 12.

As apparent from FIG. 12, compared with sample (a) including no n-type diffusion layer 4, noise power was further reduced in samples (b), (c), and (d) including one or more n-type diffusion layers 4. In sample (b) including one n-type diffusion layer 4 with a width of 10 μm, the noise power reduction effect was relatively low for noise in a high-frequency range of 1 GHz or higher. In samples (c) and (d) including a plurality of n-type diffusion layers 4, the noise power reduction effect was obtained for noise in a high-frequency range of up to about 100 GHz.

In a semiconductor device including a circuit isolation region R3 provided with n-type diffusion layers 4 having a total width of 10 μm, the relationship between the quantity of the n-type diffusion layers and noise power (S21 parameter) was analyzed three different frequencies, which are (a) 0.1 GHz (100 MHz), (b) 1 GHz, and (c) 10 GHz. The results are shown in FIG. 13.

As apparent from FIG. 13, the noise power was reduced effectively at all frequencies when the quantity of the n-type diffusion layers 4 was five or more. In particular, when the frequency was as high as 10 GHz, the effect for reducing the noise power was further enhanced. This is because the skin effect (a phenomenon in which current concentrates more in the surface as signal frequency increases) strengthens as the frequency increases. Thus, the influence of the depletion layers 6 extending across the vicinity of the surface becomes greater.

In the second embodiment of the present invention, the total width of the n-type diffusion layers 4 in the circuit isolation region R3 is 10 μm. However, if the concentration of the p-type diffusion layer is set to 1×10¹⁶ cm⁻³ and the width and interval of the n-type diffusion layers 4 are set to 0.5 μm, the area in which the n-type diffusion layers 4 are arranged may entirely be depleted. Accordingly, the resistance of this area may be increased (the conductance may be reduced), and the size of the circuit isolation region can be reduced.

FIG. 14 is a cross-sectional view showing a semiconductor device having both analog and digital circuits according to a third embodiment of the present invention. The third embodiment differs from the second embodiment in that n-type high concentration layers 7 containing impurities at a higher concentration than the n-type diffusion layers 4 are formed at the substrate surface side of the n-type diffusion layers 4 in the circuit isolation region R3. The n-type high concentration layers 7 are connected to a power supply (not shown) by a wire 9. Otherwise, the third embodiment is identical to the second embodiment.

In the third embodiment of the present invention, reverse bias is applied to the n-type diffusion layers 4 through the wire 9 and the n-type high concentration layers 7. This increases the effective width of the PN junction (the depletion layer 6) between the p-type impurity region 5 and the n-type diffusion layers 4. Thus, the resistance of the circuit isolation region R3 is increased (conductance is reduced), and the noise reduction effect is further enhanced.

The second embodiment and the third embodiment have the advantages described below.

The depletion layers 6, in which no carriers such as electrons or holes exist, increase the resistance of the circuit isolation region R3 and reduces the conductance of the circuit isolation region R3. This increases the electric resistance of the noise propagation path and suppresses the noise propagation between the two circuit regions R1 and R2.

If there are five or more n-type diffusion layers 4, the proportion of the depletion layers 6 in the circuit isolation region R3 increases. This increases the resistance of the circuit isolation region R3. Therefore, the noise propagation between the two circuit regions R1 and R2 is effectively suppressed.

As long as the depletion layers 6 are arranged side by side, the resistance of the circuit isolation region R3 increases due to the depletion layers 6 which are series-connected high impedance areas arranged between the two circuit regions R1 and R2. This effectively suppresses noise propagation between the two circuit regions R1 and R2.

The depletion layers 6 have a length L3 that is greater than at least either the width W1 or W2 of the circuit regions R1 and R2. Thus, in the widthwise direction, the depletion layers 6 completely cover the sides of the two circuit regions R1 and R2 (i.e., the boundary surface between the analog circuit region R1 and the isolation region R3 and the boundary surface between the digital circuit region R2 and the isolation region R3). Consequently, noise propagation between the two circuit regions R1 and R2 is effectively suppressed.

The depletion layers 6 have a depth that is the same as the depth of the two circuit regions R1 and R2. Thus, in the depthwise direction, the depletion layers 6 completely cover the sides of the two circuit regions R1 and R2 (i.e., the boundary surface between the analog circuit region R1 and the isolation region R3 and the boundary surface between the digital circuit region R2 and the isolation region R3). Consequently, noise propagation between the two circuit regions R1 and R2 is effectively suppressed.

It should be apparent to those skilled in the art that the present invention may be embodied in many other specific forms without departing from the spirit or scope of the invention. Particularly, it should be understood that the present invention may be embodied in the following forms.

In the first embodiment, the well and the dummy diffusion layers in the circuit isolation region R3 may have reversed conductivity types. For example, dummy diffusion layers of the P conductivity type may be formed in the well of the N conductivity type. This also suppresses noise propagation through the substrate in the circuit isolation region R3.

In the first embodiment, the dummy diffusion layers may be formed directly in the semiconductor substrate. In this case, noise propagation through the well is suppressed if the dummy diffusion layers and the semiconductor substrate have opposite conductivity types.

In the first embodiment, the conductivity type of the dummy diffusion layers may be the same as the conductivity type of the well forming the base material of the dummy diffusion layers if it is not particularly necessary to suppress the noise propagation in the well. Even in this case, the noise propagation through the surface layer of the circuit isolation region R3 is suppressed and parasitic capacitance of the signal wire extending over the circuit isolation region R3 is reduced as long as the upper surface Sb of the dummy diffusion layers is lower than the main surface Sa of the silicon substrate 10.

In the first embodiment, as long as a new manufacturing process can be added, the upper surfaces of the dummy diffusion layers may be lowered in a process differing from the process for lowering the upper surface of the well related to the formation of the epitaxial layer. If there is another manufacturing process for lowering the main surface of the silicon substrate, the upper surfaces of the dummy diffusion layers may be lowered in that process.

In the first to third embodiments, the circuit isolation region R3 may be used for dielectrically isolating circuit regions other than between the analog circuit region R1 and the digital circuit region R2.

The second and third embodiments are described with arrangements in which the n-type diffusion layers 4 are separated from each other. However, the n-type diffusion layers 4 may be integrally formed to have the shape of a comb or a meander as long as the depletion layers 6 are parallel and extend in a direction intersecting a line connecting the analog circuit region R1 and the digital circuit region R2.

In the second and third embodiments, the n-type diffusion layers 4 do not have to be linear. The n-type diffusion layers 4 may be formed to surround the periphery of one of the circuit regions R1 and R2.

The dummy diffusion layer of the first embodiment may be combined with the depletion layers 6 of the second or third embodiment.

The present examples and embodiments are to be considered as illustrative and not restrictive, and the invention is not to be limited to the details given herein, but may be modified within the scope and equivalence of the appended claims.

What is claimed is:

1. A semiconductor device comprising:
a semiconductor substrate having a main surface;
two circuit regions defined in the semiconductor substrate;
a circuit isolation region located between the two circuit regions; and
a dummy diffusion layer formed in the circuit isolation region, the dummy diffusion layer having an upper surface that is lower than the main surface of the semiconductor substrate.

2. The semiconductor device according to claim 1, wherein the dummy diffusion layer includes impurities of a first conductive type locally implanted in a base material of a second conductive type formed in the semiconductor substrate, wherein the first and second conductive types are opposite conductive types.

3. The semiconductor device according to claim 1, wherein the two circuit regions include an analog circuit region and a digital circuit region, the circuit isolation region being located between the analog circuit region and the digital circuit region.

4. The semiconductor device according to claim 1, wherein the main surface of the semiconductor substrate and the upper surface of the dummy diffusion layer form a step therebetween, with the step being filled with an insulation film layer.

5. A method for manufacturing a semiconductor device including a semiconductor substrate having a main surface, two circuit regions defined in the semiconductor substrate, and a circuit isolation region located between the two circuit regions, the method comprising the steps of:
removing part of the main surface in the circuit isolation region; and
forming a dummy diffusion layer in the circuit isolation region by implanting impurities in the removed part, with the dummy diffusion layer having an upper surface that is lower level than the main surface of the semiconductor substrate.

6. The method according to claim 5, wherein the step of forming a dummy diffusion layer includes locally implanting the impurities of a first conductive type in a base material of a second conductive type formed in the semiconductor substrate, the first and second conductive types being opposite conductive types.

7. The method according to claim 5, wherein the step for removing part of the main surface is performed simultaneously in parallel with formation of an electrode of a bipolar transistor on the main surface of the semiconductor substrate.

8. The method according to claim 5, wherein the two circuit regions include an analog circuit region and a digital circuit region, and the circuit isolation region is located between the analog circuit region and the digital circuit region.

9. The method according to claim 5, wherein the step for removing part of the main surface forms a step between the main surface of the semiconductor substrate and the upper surface of the dummy diffusion layer, the method further comprising:
filling the step with an insulation film layer.

10. A semiconductor device comprising:
a semiconductor substrate;
a first circuit region and a second circuit region defined in the semiconductor substrate; and
a circuit isolation region located between the first and second circuit regions, with the circuit isolation region including a depletion layer.

11. The semiconductor device according to claim 10, wherein the depletion layer is one of a plurality of depletion layers, with each depletion layer arranged along a direction intersecting with a line connecting the first circuit region and the second circuit region.

12. The semiconductor device according to claim 10, wherein the first and second circuit regions each have a width, and the depletion layer has a length that is greater than at least one of the widths of the first and second circuit regions.

13. The semiconductor device according to claim 10, wherein the first and second circuit regions each have a depth, and the depletion layer has a depth that is the same as the depths of the first and second circuit regions.

14. The semiconductor device according to claim 10, wherein the first circuit region is an analog circuit region and the second circuit region is a digital circuit region, and the circuit isolation region is located between the analog circuit region and the digital circuit region.

15. The semiconductor device according to claim 10, wherein the digital circuit region generates high-frequency noise of 0.1 GHz to 10 GHz.

16. The semiconductor device according to claim 10, further comprising:
a first impurity region containing impurities of a first conductivity type at a first concentration; and
a second impurity region containing impurities of a second conductivity type at a second concentration that is the same as the first concentration, the first and second impurity regions being included in the circuit isolation region, wherein the depletion layer extends along a boundary between the first impurity regions and the second impurity region.

17. The semiconductor device according to claim 16, wherein the second impurity region is one of a plurality of second impurity regions formed in the first impurity region, with boundaries between the first impurity region and the second impurity regions being arranged in a direction intersecting with a line connecting the first circuit region and the second circuit region, and the depletion layer being one of a plurality of depletion layers formed at the boundaries.

18. The semiconductor device according to claim 17, wherein the first circuit region and the second circuit region each have a dimension in a first direction, and the plurality of depletion layers have the same dimensions in the first direction, the dimensions of the plurality of depletion layers in the first direction being greater than the dimensions of the first and second circuit regions in the first direction.

19. The semiconductor device according to claim 18, wherein the plurality of depletion layers stop the propagation of high-frequency noise of 0.1 GHz to 10 GHz.
